(19) United States
(12) Patent Application Publication
(10) Pub. No.: US 2025/0280557 A1
(43) Pub. Date: Sep. 4, 2025

(54) MOS TRANSISTOR AND METHOD OF MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIDEMOTO TOMITA, Nisshin-shi (JP); TSUNENOBU KIMOTO, Kyoto (JP)

(21) Appl. No.: 18/985,217

(22) Filed: Dec. 18, 2024

(30) Foreign Application Priority Data
Mar. 4, 2024 (JP) 2024-032484

(51) Int. Cl. H10D 30/01; H10D 30/66; H10D 62/832

(52) U.S. Cl. CPC H10D 30/0297; H10D 30/668; H10D 62/8325

(57) ABSTRACT

A method of manufacturing a MOS transistor includes: etching a surface of a SiC substrate with hydrogen gas in a state where the SiC substrate is heated to a temperature of 1200° C. or higher; forming an amorphous silicon layer on the surface of the SiC substrate after the etching; forming a gate insulating film made of silicon oxide on a surface of the amorphous silicon layer by a chemical vapor deposition; and performing a nitrogen termination treatment on the SiC substrate after the forming of the gate insulating film.

### CROSS REFERENCE TO RELATED APPLICATION

This application is based on Japanese Patent Application No. 2024-032484 filed on Mar. 4, 2024, the disclosure of which is incorporated herein by reference.

### TECHNICAL FIELD

The present disclosure relates to a MOS transistor and a method of manufacturing the MOS transistor.

### BACKGROUND

In a method for manufacturing a MOS transistor, a substrate made of SiC (silicon carbide) is etched with hydrogen gas (H₂) in a silicon-rich atmosphere. As a result, the surface of the SiC substrate is cleaned, and a thin film of silicon crystal (Si) is formed on the surface of the SiC substrate. Next, a silicon oxide (SiO₂) film is formed as a gate insulating film on the surface of the thin film of silicon. At this time, the thin film of silicon is oxidized, thereby suppressing oxidation of the surface of the SiC substrate. By suppressing the oxidation of the surface of the SiC substrate in this manner, the density of interface states at the interface between the silicon oxide film and the SiC substrate can be reduced. The density of interface states at the interface between the silicon oxide film and the SiC substrate is reduced, thereby improving channel mobility and decreasing channel resistance. This makes it possible to reduce the on-resistance of the MOS transistor.

### SUMMARY

According to one aspect of the present disclosure, a method of manufacturing a MOS transistor includes: etching a surface of a SiC substrate with hydrogen gas in a state where the SiC substrate is heated to a temperature of 1200° C. or higher; forming an amorphous silicon layer on the surface of the SiC substrate after performing the etching with hydrogen gas; forming a gate insulating film made of silicon oxide on a surface of the amorphous silicon layer by chemical vapor deposition; and performing a nitrogen termination treatment on the SiC substrate after forming the gate insulating film.

### BRIEF DESCRIPTION OF DRAWINGS

FIG. 1 is a cross-sectional view of a MOS transistor according to an embodiment.

FIG. 2A is a view for explaining a manufacturing method in the embodiment.

FIG. 2B is a view for explaining a manufacturing method in the embodiment.

FIG. 3A is a view for explaining a manufacturing method in the embodiment.

FIG. 3B is a view for explaining a manufacturing method in the embodiment.

FIG. 3C is a view for explaining a manufacturing method in the embodiment.

FIG. 3D is a view for explaining a manufacturing method in the embodiment.

FIG. 4 is an electron diffraction image of an amorphous layer.

FIG. 5 is a view showing a shoulder portion of a gate structure formed by a manufacturing method (high-temperature hydrogen etching for 15 minutes) in the embodiment.

FIG. 6 is a view showing a shoulder portion of a gate structure formed by a manufacturing method (high-temperature hydrogen etching for 30 minutes) in the embodiment.

FIG. 7 is a view showing a shoulder portion of a gate structure formed by a manufacturing method of a comparative example.

FIG. 8 shows results of evaluation in breakdown voltage relative to gate insulating films of FIGS. 5 to 7.

### DETAILED DESCRIPTION

In a method for manufacturing a MOS transistor, a substrate made of SiC (silicon carbide) is etched with hydrogen gas (H₂) in a silicon-rich atmosphere. As a result, the surface of the SiC substrate is cleaned, and a thin film of silicon crystal (Si) is formed on the surface of the SiC substrate. Next, a silicon oxide (SiO₂) film is formed as a gate insulating film on the surface of the thin film of silicon. At this time, the thin film of silicon is oxidized, thereby suppressing oxidation of the surface of the SiC substrate. By suppressing the oxidation of the surface of the SiC substrate in this manner, the density of interface states at the interface between the silicon oxide film and the SiC substrate can be reduced. The density of interface states at the interface between the silicon oxide film and the SiC substrate is reduced, thereby improving channel mobility and decreasing channel resistance. This makes it possible to reduce the on-resistance of the MOS transistor.

After the silicon oxide film is formed, a nitrogen termination treatment is performed. The nitrogen termination treatment can further reduce the density of interface states at the interface between the silicon oxide film and the SiC substrate.

This specification proposes a method of manufacturing a MOS transistor with low on-resistance.

According to one aspect of the present disclosure, a method of manufacturing a MOS transistor includes: etching a surface of a SiC substrate with hydrogen gas in a state where the SiC substrate is heated to a temperature of 1200° C. or higher; forming an amorphous silicon layer on the surface of the SiC substrate after performing the etching with hydrogen gas; forming a gate insulating film made of silicon oxide on a surface of the amorphous silicon layer by chemical vapor deposition; and performing a nitrogen termination treatment on the SiC substrate after forming the gate insulating film.

In this manufacturing method, the surface of the SiC substrate is cleaned by etching with hydrogen gas. Thereafter, the amorphous silicon layer is formed on the surface of the SiC substrate. Next, the gate insulating film made of silicon oxide is formed on the surface of the amorphous silicon layer by chemical vapor deposition (hereinafter, referred to as CVD). When the gate insulating film is formed, the amorphous silicon layer is oxidized to form silicon oxide. This suppresses oxidation of the surface of the SiC substrate. Thereafter, the SiC crystal is terminated with nitrogen at the interface between the gate insulating film and the SiC substrate by nitrogen termination treatment. According to this manufacturing method, oxidation of the SiC substrate can be suppressed during the formation of the gate insulating film, so that the density of interface states at the interface between the gate insulating film and the SiC substrate can be reduced. Therefore, according to this manufacturing method, it is possible to reduce the channel resistance, and to manufacture a MOS transistor having a low on-resistance.

In an aspect of the present disclosure, a manufacturing method of a MOS transistor, a trench is provided on the main surface of the SiC substrate. In the step of etching the surface of the SiC substrate, a side surface of the trench is etched with hydrogen gas. In the step of forming an amorphous silicon layer, the amorphous silicon layer is formed on a side surface of the trench. In the step of forming the gate insulating film, the gate insulating film is formed on a surface of the amorphous silicon layer covering the side surface of the trench.

Accordingly, it is possible to suitably manufacture a trench-gate type MOS transistor having a low on-resistance, as will be described below. In a comparative hydrogen etching process, since a SiC substrate is etched with hydrogen in a silicon-rich atmosphere, a silicon thin film cannot be suitably formed on the side surface of the trench. In this trench-gate MOS transistor, it is not possible to reduce the density of interface states at the interface between the gate insulating film and the SiC substrate (that is, the side surface of the trench). With the technique in the comparative example, it is difficult to reduce the channel resistance in the trench-gate MOS transistor, and it is difficult to manufacture a trench-gate MOS transistor with a low on-resistance.

In contrast, according to the present disclosure, the side surface of the trench is cleaned by etching with hydrogen gas. Thereafter, an amorphous silicon layer is formed on the side surface of the trench. The amorphous silicon layer can be suitably formed on the sidewalls of the trench. Next, a gate insulating film made of silicon oxide is formed on the surface of the amorphous silicon layer by chemical vapor deposition (hereinafter, referred to as CVD). When the gate insulating film is formed, the amorphous silicon layer is oxidized to form silicon oxide. This restrict the side surfaces of the trench from being oxidized. Thereafter, the SiC crystal is terminated with nitrogen at the interface between the gate insulating film and the SiC substrate by nitrogen termination treatment. In this way, according to the manufacturing method of the present disclosure, oxidation of the side surface of the trench can be suppressed during formation of the gate insulating film, thereby reducing the density of interface states at the interface between the gate insulating film and the SiC substrate. Therefore, according to this manufacturing method, it is possible to reduce the channel resistance, and to manufacture a trench-gate MOS transistor having a low on-resistance.

For example, the etching with hydrogen gas etches the main surface of the SiC substrate in addition to the side surface of the trench. In the step of forming the amorphous silicon layer, the amorphous silicon layer is formed not only the side surface of the trench but also on the main surface of the SiC substrate. In the step of forming the gate insulating film, the gate insulating film is formed on the surface of the amorphous silicon layer in an area covering the side surface of the trench and the main surface of the SiC substrate.

Further, the amorphous silicon layer may be formed by chemical vapor deposition.

This configuration allows the amorphous silicon layer to be formed suitably.

For example, the amorphous silicon layer may be formed in a nitrogen atmosphere by chemical vapor deposition in a state where the SiC substrate is heated to a temperature of 400° C. or more and 550° C. or less.

This configuration allows the amorphous silicon layer to be formed suitably.

For example, the amorphous silicon layer may be formed by chemical vapor deposition in a state where the SiC substrate is placed under a pressure of 0.3 Torr or more and 1.0 Torr or less.

This configuration allows the amorphous silicon layer to be formed suitably.

For example, the amorphous silicon layer on the side surface of the trench may have a thickness of 6 nm or less.

If the amorphous silicon layer is too thick, a part of the amorphous silicon layer may remain unoxidized. In contrast, when the thickness of the amorphous silicon layer is 6 nm or less, it is possible to restrict the amorphous silicon layer from remaining without being oxidized.

For example, the main surface of the SiC substrate is a surface of an epitaxial layer.

Further, the nitrogen termination treatment may involve heating the SiC substrate to a temperature of 1200° C. or higher in nitrogen gas or nitrogen oxide gas.

For example, after formation of the gate insulating film, the main surface of the SiC substrate and the side surface of the trench are connected by an arc having a minimum radius of curvature of 53 nm or more in a cross section along a direction perpendicular to the trench in the main surface of the SiC substrate and along a thickness direction of the SiC substrate.

According to this configuration, current leakage at the boundary between the main surface of the SiC substrate and the side surface of the trench can be suppressed.

For example, after formation of the gate insulating film, the main surface of the SiC substrate and the side surface of the trench are connected by an elliptical or circular arc with an aspect ratio of 0.29 or less in a cross section along a direction perpendicular to the trench on the main surface of the SiC substrate and along a thickness direction of the SiC substrate.

According to this configuration, current leakage at the boundary between the main surface of the SiC substrate and the side surface of the trench can be suppressed.

According to another aspect of the present disclosure, a MOS transistor includes: a SiC substrate having a trench provided on a main surface thereof; a gate insulating film covering a side surface of the trench; and a gate electrode provided in the trench. In a cross section along a direction perpendicular to the trench on the main surface and along a thickness direction of the SiC substrate, the main surface of the SiC substrate and the side surface of the trench are connected with each other by an arc having a minimum radius of curvature of 53 nm or more.

According to this configuration, current leakage at the boundary between the main surface of the SiC substrate and the side surface of the trench can be suppressed.

According to another aspect of the present disclosure, a MOS transistor includes: a SiC substrate having a trench provided on a main surface thereof; a gate insulating film covering a side surface of the trench; and a gate electrode provided in the trench. In a cross section along a direction perpendicular to the trench on the main surface and along a thickness direction of the SiC substrate, the main surface of the SiC substrate and the side surface of the trench are connected with each other by an elliptical or circular arc having an aspect ratio of 0.29 or less.

According to this configuration, current leakage at the boundary between the main surface of the SiC substrate and the side surface of the trench can be suppressed.

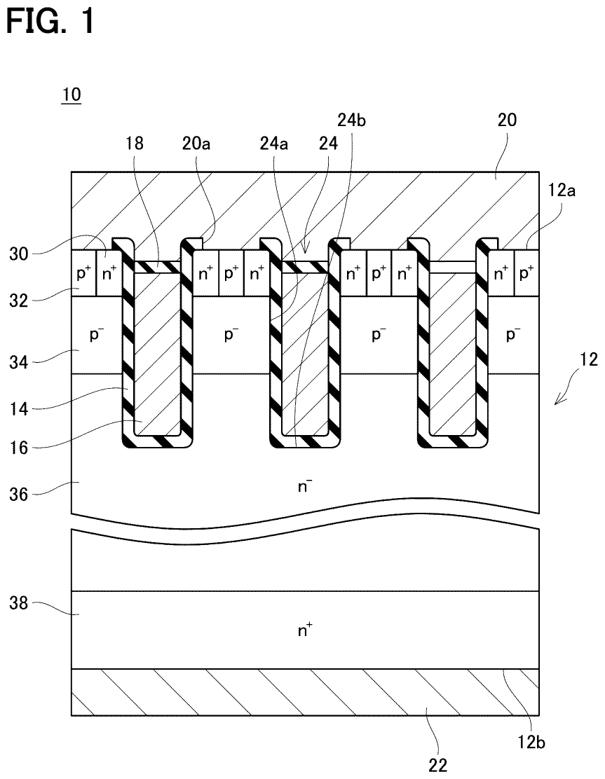

FIG. 1 shows a MOS transistor 10 manufactured by a manufacturing method according to an embodiment. The MOS transistor 10 includes a SiC substrate 12, a gate insulating film 14, a gate electrode 16, an interlayer insulating film 18, a source electrode 20, and a drain electrode 22. The SiC substrate 12 has an upper surface (main surface) 12a and a lower surface 12b. Trenches 24 are provided in the upper surface 12a of the SiC substrate 12. The trenches 24 extend linearly and parallel to each other on the upper surface 12a. The gate insulating film 14 covers the inner surface of each trench 24 (specifically, the side surface 24a and the bottom surface 24b of the trench 24). The gate electrode 16 is disposed in each trench 24. The gate electrode 16 is insulated from the SiC substrate 12 by the gate insulating film 14. The interlayer insulating film 18 covers an upper surface of the gate electrode 16. The source electrode 20 covers the upper surface 12a of the SiC substrate 12 and the upper surface of the interlayer insulating film 18. The source electrode 20 is insulated from the gate electrode 16 by the interlayer insulating film 18. The drain electrode 22 covers the lower surface 12b of the SiC substrate 12.

The SiC substrate 12 has a source region 30, a contact region 32, a body region 34, a drift region 36, and a drain region 38. The source region 30 is an n-type region having a high n-type impurity concentration. The source region 30 is in contact with the source electrode 20 and the gate insulating film 14. The contact region 32 is a p-type region having a high concentration of p-type impurities. The contact region 32 is in contact with the source electrode 20. The body region 34 is a p-type region having a lower p-type impurity concentration than the contact region 32. The body region 34 is in contact with the source region 30 and the contact region 32 from the lower side. The body region 34 is in contact with the gate insulating film 14 at a position below the source region 30. The drift region 36 is an n-type region having a lower n-type impurity concentration than the source region 30. The drift region 36 is in contact with the body region 34 from the lower side. The drift region 36 is in contact with the gate insulating film 14 at a position below the body region 34. The drain region 38 is an n-type region having a higher n-type impurity concentration than the drift region 36. The drain region 38 is in contact with the drift region 36 from the lower side. The drain region 38 is in contact with the drain electrode 22.

When a potential equal to or higher than a threshold is applied to the gate electrode 16, a channel is formed in the body region 34 along the gate insulating film 14 (along the side surface 24a of the trench 24). A channel connects the source region 30 and the drift region 36. When a potential higher than that of the source electrode 20 is applied to the drain electrode 22 while the channel is formed, electrons flow from the source region 30 through the channel and the drift region 36 to the drain region 38.

Next, a method for manufacturing the MOS transistor 10 will be described in the embodiment. According to the manufacturing method of the embodiment, it is possible to manufacture the MOS transistor 10 having a low on-resistance. The manufacturing method in the embodiment includes forming a trench gate structure. In each drawing explaining the manufacturing method, illustration of the p-type region and the n-type region in the SiC substrate 12 is omitted.

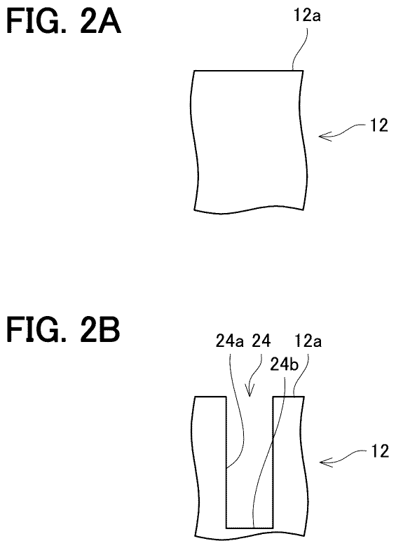

As shown in FIG. 2A, the SiC substrate 12, before the trenches are formed, is prepared. The SiC layer exposed at the upper surface 12a is an epitaxial layer formed by epitaxial growth. Although not shown in FIG. 2A, the source region 30, the contact region 32, the body region 34, the drift region 36, and the drain region 38 are provided in the SiC substrate 12.

As shown in FIG. 2B, the upper surface 12a of the SiC substrate 12 is selectively etched to form the trench 24 in the upper surface 12a.

A surface portion of the SiC substrate 12 has a high density of carbon defects having C—C bond. The carbon defects form interface states and trap electrons. If the carbon defects are present at a high density at the interface between the side surface 24a of the trench 24 and the gate insulating film 14, Coulomb scattering occurs due to electrons and the like captured at the interface states. In this case, the channel mobility decreases and the channel resistance increases. In contrast, as described below, in the manufacturing method of the embodiment, the gate structure can be formed in a state in which the density of interface states on the side surface 24a of the trench 24 is low.

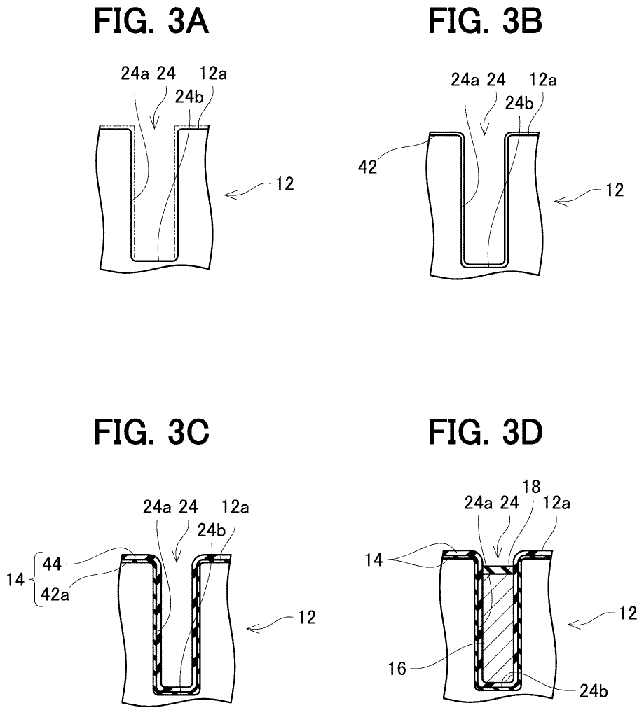

After forming the trench 24 as shown in FIG. 2B, high-temperature hydrogen etching is performed as shown in FIG. 3A. In the high-temperature hydrogen etching, the SiC substrate 12 is heated to a temperature of 1200° C. or higher (for example, 1300° C.) in hydrogen (H₂) gas. Then, the surface of the SiC substrate 12 (specifically, the upper surface 12a and the inner surface of the trench 24) is etched by the hydrogen gas. Here, a very thin layer near the surface of the SiC substrate 12 is etched. As a result, carbon defects can be removed from the surface of the SiC substrate 12. That is, the density of carbon defects on the surface of the SiC substrate 12 can be reduced by the high-temperature hydrogen etching.

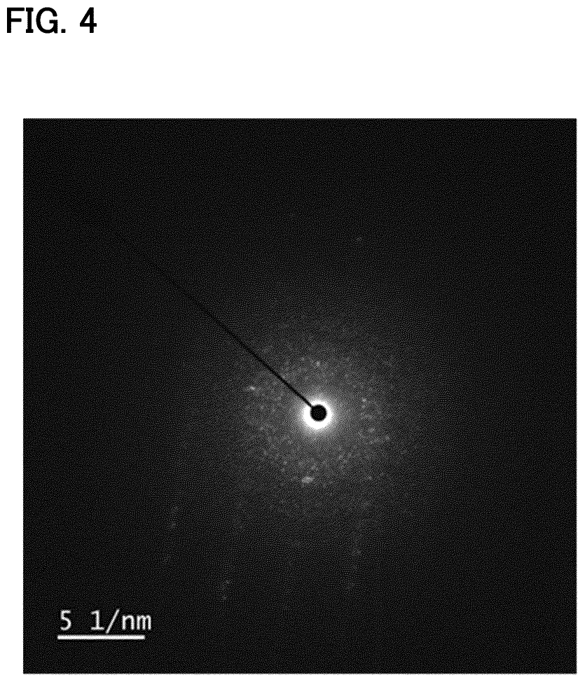

Next, a step of forming an amorphous silicon layer shown in FIG. 3B is conducted. For example, a low-pressure CVD apparatus is used to form a silicon layer on the surface of the SiC substrate 12 in a nitrogen atmosphere. For example, SiH₄ gas and N₂ gas are used. The temperature for forming the film can be controlled to a temperature of 400° C. or more and 550° C. or less, and the pressure for forming the film can be controlled to a pressure of 0.3 Torr or more and 1.0 Torr or less. When CVD is performed under the low-temperature and low-pressure condition, the silicon layer grows at a slow speed. As a result, an amorphous silicon layer 42 is formed with a relatively uniform thickness on the upper surface 12a of the SiC substrate 12 and on the inner surface of the trench 24. FIG. 4 shows an electron diffraction image of the amorphous silicon layer 42 formed on the side surface of the trench 24 by this method. As shown in FIG. 4, a broad halo pattern is observed, and it is confirmed that the silicon layer formed on the side surface of the trench 24 is amorphous.

Furthermore, when CVD is performed under such conditions, the surface roughness of the amorphous silicon layer 42 can be reduced. For example, the flow rate of SiH₄ gas can be controlled to 250 sccm, and the flow rate of N₂ gas can be controlled to 230 sccm. The amorphous silicon layer 42 is formed so that the thickness of the amorphous silicon layer 42 on the side surface 24a is 6 nm or less by adjusting the time for forming the film.

Next, a step of forming a gate insulating film shown in FIG. 3C is conducted. A silicon oxide layer 44 is formed on the surface of the amorphous silicon layer 42 using a low-pressure CVD apparatus. That is, the silicon oxide layer 44 is formed on the top of the upper surface 12a and inside the trench 24.

Next, nitrogen termination treatment is carried out. In the nitrogen termination treatment, the SiC substrate 12 is heated to a temperature of 1200° C. or higher (such as 1250° C.) in nitrogen gas (N₂ gas) or nitrogen oxide gas (such as NO gas, N₂O gas, N₂ gas, and the like). This causes the SiC crystal to be nitrogen-terminated.

In a comparative manufacturing method, the surface of the SiC substrate is oxidized in the step of forming the gate insulating film. Furthermore, in a comparative manufacturing method, the surface of the SiC substrate may be oxidized during the nitrogen termination treatment. For example, when nitrogen oxide gas is used in the nitrogen termination treatment, the surface of the SiC substrate may be oxidized by oxygen atoms in the nitrogen oxide gas. Even when nitrogen gas is used in the nitrogen termination treatment, the surface of the SiC substrate may be oxidized by a small amount of oxidizing gas mixed into the chamber. When the surface of the SiC substrate is oxidized in the step of forming the gate insulating film and the nitrogen termination treatment, carbon defects are generated on the surface of the SiC substrate.

In contrast, in this embodiment, in the step of forming the gate insulating film and the nitrogen termination treatment shown in FIG. 3C, the amorphous silicon layer 42 is oxidized instead of the SiC substrate 12. The silicon oxide layer 42a formed by oxidizing the amorphous silicon layer 42 is integrated with the silicon oxide layer 44 formed by CVD. Thus, the gate insulating film 14 is formed. Furthermore, since the amorphous silicon layer 42 is oxidized instead of the SiC substrate 12, oxidation of the surface of the SiC substrate 12 is suppressed. Therefore, carbon defects are unlikely to be generated on the surface of the SiC substrate 12 (specifically, the interface between the SiC substrate 12 and the gate insulating film 14). As a result, the density of interface states on the surface of the SiC substrate 12 can be reduced. Due to this effect and the effect of terminating the SiC crystal with nitrogen by the nitrogen termination treatment, the density of interface states at the interface between the SiC substrate 12 and the gate insulating film 14 can be significantly reduced. In this embodiment, since the amorphous silicon layer 42 can be formed on the side surface 24a of the trench 24, the density of interface states can be significantly reduced on the side surface 24a (specifically, the interface between the SiC substrate 12 and the gate insulating film 14).

Next, as shown in FIG. 3D, the gate electrode 16 is formed in the trench 24. In addition, the interlayer insulating film 18 is formed on the gate electrode 16. This completes the trench gate structure.

Next, as shown in FIG. 1, the gate insulating film 14 on the upper surface 12a is selectively removed to form a contact hole 20a. Next, the source electrode 20 is formed to cover the upper surface 12a of the SiC substrate 12. Next, the drain electrode 22 is formed to cover the lower surface 12b of the SiC substrate 12. Through the above steps, the MOS transistor 10 shown in FIG. 1 is completed.

According to the manufacturing method of the embodiment, carbon defects present on the side surface 24a of the trench 24 can be removed by high-temperature hydrogen etching. Furthermore, according to the manufacturing method of the embodiment, the amorphous silicon layer 42 is oxidized in the step of forming the gate insulating film and the nitrogen termination treatment, so that oxidation of the SiC substrate 12 can be suppressed and the generation of carbon defects on the side surface 24a of the trench 24 can be suppressed. Moreover, according to the manufacturing method of the embodiment, the density of interfaces state at the interface between the SiC substrate 12 and the gate insulating film 14 can be reduced by the nitrogen termination treatment. Therefore, it is possible to manufacture the MOS transistor 10 having a low density of interface states on the side surface 24a (specifically, the interface between the body region 34 and the gate insulating film 14). Therefore, according to this manufacturing method, the channel resistance of the MOS transistor 10 can be reduced. That is, according to this manufacturing method, the MOS transistor 10 having a low on-resistance can be manufactured.

The characteristics of the MOS transistor 10 manufactured by the manufacturing method of the embodiment (hereinafter referred to as the embodiment prototype) and a MOS transistor manufactured by a conventional manufacturing method (hereinafter referred to as the conventional product) are evaluated. It is confirmed that the embodiment prototype could achieve a higher channel mobility than the conventional product. Also, in the conventional product, the channel mobility decreases as the temperature decreases, whereas in the embodiment prototype, the channel mobility increases as the temperature decreases. This is believed to be because in the embodiment prototype, the density of interface states is reduced, resulting in a reduction in the influence of Coulomb scattering at low temperature. Moreover, it is confirmed that the embodiment prototype has a greater effect of reducing the on-resistance of the element than the conventional product. This is believed to be because in the embodiment prototype, the channel resistance is reduced due to the increased channel mobility. It is also confirmed that the embodiment prototype has the same withstand voltage as the conventional product.

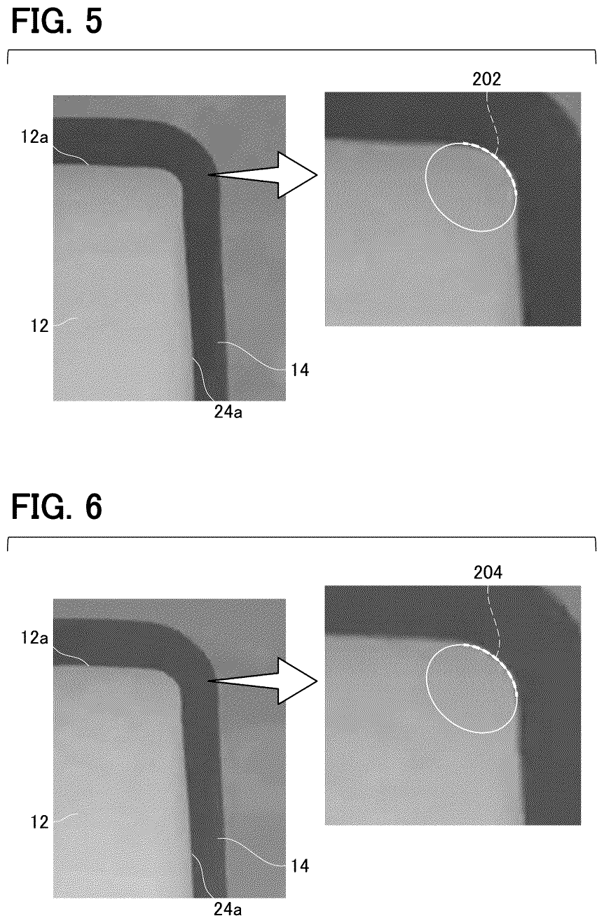

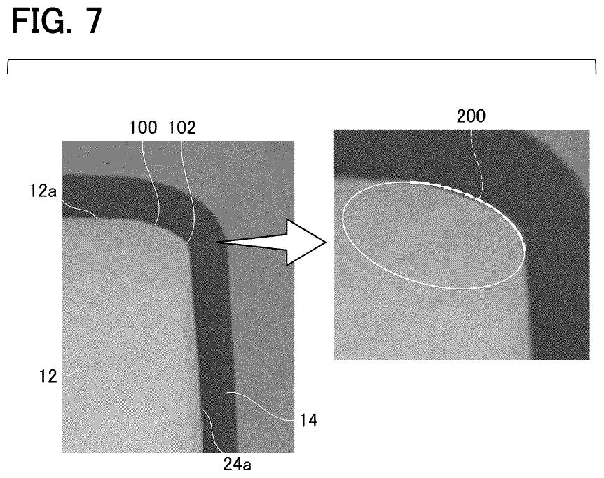

FIGS. 5 to 7 show cross sections, at the upper surface 12a, along a direction perpendicular to an extending direction of the trench 24 and along a thickness direction of the SiC substrate 12. FIGS. 5 and 6 show enlarged views of the boundary portion (hereinafter referred to as shoulder portion) between the side surface 24a and the upper surface 12a when the gate insulating film 14 is formed by the manufacturing method of the embodiment. More specifically, FIG. 5 shows the shape of the shoulder portion when the sacrificial oxide film forming step and the sacrificial oxide film removing step are not performed, and high-temperature hydrogen etching is performed for 15 minutes. FIG. 5 corresponds to the MOS transistor 10 manufactured by the manufacturing method of the embodiment (hereinafter, referred to as the embodiment prototype). FIG. 6 shows the shape of the shoulder portion when the sacrificial oxide film forming step and the sacrificial oxide film removing step are not performed and high-temperature hydrogen etching is performed for 30 minutes. FIG. 7 shows an enlarged view of a shoulder portion when the gate insulating film 14 is formed by the manufacturing method of the comparative example. More specifically, FIG. 7 shows the shape of the shoulder portion when the sacrificial oxide film forming step and the sacrificial oxide film removing step are performed, and argon etching is performed instead of high-temperature hydrogen etching.

In argon etching, the etching rate is significantly different between the upper surface 12a and the side surface 24a, and etching of the upper surface 12a proceeds faster than etching of the side surface 24a. For this reason, as shown in FIG. 7, an inclined portion 100 is formed in the shoulder portion, which is gradually sloped downward as approaching the trench. Furthermore, in a bent portion 102 between the inclined portion 100 and the side surface 24a, the surface of the SiC substrate 12 is curved with a small radius of curvature. That is, in FIG. 7, the radius of curvature of the shoulder portion is the smallest at the bent portion 102. Specifically, the value of the radius of curvature is 47 nm at the bent portion 102. A dashed line 200 shown in FIG. 7 indicates a shoulder portion connecting the upper surface 12a and the side surface 24a as an elliptical arc. The aspect ratio of the ellipse of the elliptical arc 200 is 0.40. The aspect ratio (flattening ratio) f is a value expressed by f=1−b/a, where “a” is the semimajor axis of an ellipse and “b” is the semiminor axis of the ellipse. In the argon etching, the etching rate of the upper surface 12a is faster than that of the side surface 24a, so that the aspect ratio of the elliptical arc 200 is large.

In contrast, according to the high-temperature hydrogen etching, the upper surface 12a and the side surfaces 24a are etched more uniformly than argon etching. Therefore, as shown in FIGS. 5 and 6, a locally small radius of curvature (such as the bent portion 102 in FIG. 7) is not formed in the shoulder portion between the upper surface 12a and the side surface 24a. Therefore, the high-temperature hydrogen etching increases the minimum radius of curvature at the shoulder portion. For example, the minimum radius of curvature of the shoulder portion is 53 nm in FIG. 5, and is 71 nm in FIG. 6. A dashed line 202, 204 in FIGS. 5 and 6 show a shoulder portion connecting the upper surface 12a and the side surface 24a as elliptical arc. In FIG. 5, the aspect ratio of the elliptical arc 202 is 0.29. In FIG. 6, the aspect ratio of the elliptical arc 204 is 0.25. That is, the aspect ratio of the elliptical arc in FIGS. 5 and 6 is smaller than that in FIG. 7. That is, the elliptical arc in FIGS. 5 and 6 is closer to a perfect circle arc than that in FIG. 7. In the high-temperature hydrogen etching, the upper surface 12a and the side surface 24a are etched more uniformly than in the argon etching, so that the aspect ratio of the elliptical arc 202, 204 can be made smaller.

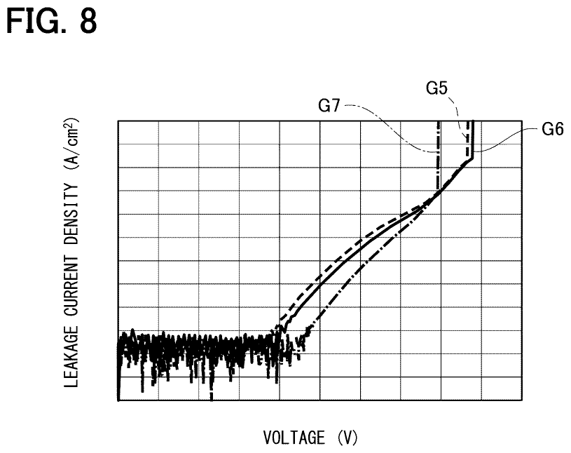

FIG. 8 shows the results of evaluating the breakdown voltage of the gate insulating film 14 at the shoulder position. The horizontal axis of FIG. 8 represents the voltage applied to the gate insulating film 14, and the vertical axis of FIG. 8 represents the leakage current flowing through the gate insulating film 14. Graphs G5, G6, and G7 in FIG. 8 respectively show the results for the MOS transistors of FIGS. 5, 6 and 7. As shown in FIG. 8, the graphs G5 and G6 provide higher withstand voltage than the graph G7. It can be seen from FIG. 8 that when the minimum value of the radius of curvature of the shoulder portion is 53 nm or more and the aspect ratio of the elliptical arc of the shoulder portion is 0.29 or less, the withstand voltage is stable at a high value. In this way, the high-temperature hydrogen etching can form the shoulder portion into a smoother curved shape, making it possible to increase the withstand voltage.

In the embodiment, a method for manufacturing a trench MOS transistor has been described. However, the techniques disclosed herein may also be applied to a manufacturing method of MOS transistor having a planar gate structure. In this case, the technique disclosed in this specification makes it possible to form a gate insulating film to cover the main surface (specifically, the upper surface) of the SiC substrate.

Although the embodiment has been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A method of manufacturing a MOS transistor comprising:
etching a surface of a SiC substrate with hydrogen gas in a state where the SiC substrate is heated to a temperature of 1200° C. or higher;
forming an amorphous silicon layer on the surface of the SiC substrate after the etching;
forming a gate insulating film made of silicon oxide on a surface of the amorphous silicon layer by chemical vapor deposition; and
performing a nitrogen termination treatment on the SiC substrate after the forming of the gate insulating film.

2. The method according to claim 1, wherein
a trench is provided in a main surface of the SiC substrate,
the etching includes etching a side surface of the trench with hydrogen gas,
the forming of the amorphous silicon layer includes forming the amorphous silicon layer on the side surface of the trench, and
the forming of the gate insulating film includes forming the gate insulating film on the surface of the amorphous silicon layer covering the side surface of the trench.

3. The method according to claim 2, wherein
the etching includes etching the side surface of the trench and the main surface of the SiC substrate,
the forming of the amorphous silicon layer includes forming the amorphous silicon layer on the side surface of the trench and on the main surface of the SiC substrate, and
the forming of the gate insulating film includes forming the gate insulating film on the surface of the amorphous silicon layer within an area covering the side surface of the trench and the main surface of the SiC substrate.

4. The method according to claim 1, wherein the amorphous silicon layer is formed by chemical vapor deposition.

5. The method according to claim 4, wherein the amorphous silicon layer is formed in a nitrogen atmosphere by chemical vapor deposition in a state where the SiC substrate is heated to a temperature of 400° C. or more and 550° C. or less.

6. The method according to claim 4, wherein the amorphous silicon layer is formed by chemical vapor deposition in a state where the SiC substrate is placed under a pressure of 0.3 Torr or more and 1.0 Torr or less.

7. The method according to claim 1, wherein the amorphous silicon layer has a thickness of 6 nm or less.

8. The method according to claim 1, wherein a main surface of the SiC substrate is a surface of an epitaxial layer.

9. The method according to claim 1, wherein the nitrogen termination treatment includes heating the SiC substrate to a temperature of 1200° C. or higher in nitrogen gas or nitrogen oxide gas.

10. The method according to claim 2, wherein
the main surface of the SiC substrate and the side surface of the trench are connected by an arc having a minimum radius of curvature of 53 nm or more, in a cross section of the main surface of the SiC substrate along a direction perpendicular to the trench and a thickness direction of the SiC substrate, after the gate insulating film is formed.

11. The method according to claim 2, wherein
the main surface of the SiC substrate and the side surface of the trench are connected by an elliptical or circular arc having an aspect ratio of 0.29 or less, in a cross section of the main surface of the SiC substrate along a direction perpendicular to the trench and a thickness direction of the SiC substrate, after the gate insulating film is formed.

12. A trench gate MOS transistor comprising:
a SiC substrate having a trench provided on a main surface of the SiC substrate;
a gate insulating film covering a side surface of the trench; and
a gate electrode provided in the trench, wherein
the main surface of the SiC substrate and the side surface of the trench are connected by an arc having a minimum radius of curvature of 53 nm or more in a cross section of the main surface along a direction perpendicular to the trench and a thickness direction of the SiC substrate.

13. A trench gate MOS transistor comprising:
a SiC substrate having a trench provided on a main surface of the SiC substrate;
a gate insulating film covering a side surface of the trench; and
a gate electrode provided in the trench, wherein
the main surface of the SiC substrate and the side surface of the trench are connected by an elliptical or circular arc having an aspect ratio of 0.29 or less in a cross section of the main surface along a direction perpendicular to the trench and a thickness direction of the SiC substrate.
